(19) United States
(12) Patent Application Publication
(10) Pub. No.: US 2015/0340544 A1
(43) Pub. Date: Nov. 26, 2015

(54) METHOD FOR ANNEALING A THIN FILM PHOTOVOLTAIC CELL DEVICE

(71) Applicant: TEL Solar AG, Trubbach (CH)

(72) Inventors: Simon Hänni, Tramelan (CH); Laura Ding, Corserey (CH)

(73) Assignee: TEL Solar AG, Trubbach (CH)

(21) Appl. No.: 14/286,597

(22) Filed: May 23, 2014

(51) Int. Cl. H01L 31/18; H01L 31/0368; H01L 31/077

(52) U.S. Cl. CPC H01L 31/1864; H01L 31/077; H01L 31/03685

(57) ABSTRACT

A method of method for annealing a thin film solar cell device is described. The method includes vacuum annealing an as-deposited photovoltaic cell stack composed of a first electrode, a p-i-n junction having at least one p-doped layer, at least one n-doped layer, and at least one intrinsic layer disposed there between, and a second electrode. The vacuum annealing is performed in a non-plasma, vacuum environment by elevating a temperature of the photovoltaic cell stack to an anneal temperature within the range of between 150 degrees C. and 250 degrees C.

### BACKGROUND OF THE INVENTION

1. Field of Invention

The invention relates to a method for treating a layer in a photovoltaic (PV) cell, and more particularly, to a method for annealing a Si-containing layer in a PV cell.

2. Description of Related Art

Thin-film silicon photovoltaics (TF-Si PV), based on the use of abundant and non-toxic elements, has a unique potential for a large-scale deployment of renewable electricity production. However, an efficiency increase will be required to stay competitive in the nowadays harsh market and to alleviate the impact of the balance-of system costs. Microcrystalline silicon (μc-Si:H) is efficiently used as bottom cell in tandem or triple cell configurations, and is usually considered as stable with respect to light-induced degradation when used in such a configuration. It is however known to be sensitive to contamination by impurities and moisture-related post-deposition oxidation. Indeed, even short times of storage in ambient atmosphere may induce losses in electrical performance. Nevertheless, these losses can often be minimized with adequate deposition process for the absorber layer and recovered (at least partially) when the cells are annealed or properly encapsulated.

Recently, post-deposition treatment of the solar cells based on a hydrogen plasma was introduced that improves the electrical performance of μc-Si:H solar cells deposited on rough superstrates; however without any investigation on the separate effects coming from the μc-Si:H absorber layer or the front- and back electrodes, made of zinc oxide (ZnO). Post-deposition treatment of ZnO is a widely investigated field. Several methods, such as ion implantation, annealing, or hydrogen plasma, have been used to improve the electrical properties of ZnO.

Such a treatment was developed for ZnO layers deposited on glass by low-pressure chemical vapor deposition (LPCVD ZnO). Therein, a strong increase in the charge carrier mobility and a moderate increase in the carrier density was observed, leading to a significant decrease in sheet resistance. The effect was more pronounced in the case of lightly doped ZnO and was attributed to modification in the charged trap density at the grain boundaries. When applying a hydrogen plasma on a complete solar cell (without white dielectric back reflector, i.e. with the ZnO back electrode directly exposed to the plasma), an increase of the open circuit voltage (V_{oc}), as well as of the fill factor (FF), was observed, whereas the short-circuit current density (J_{sc}) was almost unaffected (±1%). While these results are attractive, plasma treatment can be less cost-effective, and therefore, other techniques are explored.

### SUMMARY OF THE INVENTION

Embodiments of the invention relate to a method for treating a layer in a photovoltaic (PV) cell, and more particularly, to a method for annealing a Si-containing layer, such as a micro-crystalline silicon layer, in a PV cell.

According to one embodiment, a method for annealing a thin film solar cell device is described. The method includes vacuum annealing an as-deposited photovoltaic cell stack composed of a first electrode, a p-i-n junction having at least one p-doped layer, at least one n-doped layer, and at least one intrinsic layer disposed there between, and a second electrode. The vacuum annealing is performed in a non-plasma, vacuum environment by elevating a temperature of the photovoltaic cell stack to an anneal temperature within the range of between 150 degrees C. and 250 degrees C.

### BRIEF DESCRIPTION OF THE DRAWINGS

In the accompanying drawings:

FIG. 1 provides a flow chart depicting a method for annealing a thin film photovoltaic device;

FIGS. 2A and 2B provide schematic views of various p-i-n structure μc-Si:H photovoltaic cells;

FIGS. 3A and 3B show the effect of a hydrogen plasma and vacuum annealing on the V_{oc} and FF of μc-Si:H photovoltaic cells; and

FIG. 4 shows a result from the measurement of the sub-gap absorption of μc-Si:H photovoltaic cells.

### DETAILED DESCRIPTION OF SEVERAL EMBODIMENTS

Methods for annealing PV devices/modules are described in various embodiments. One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

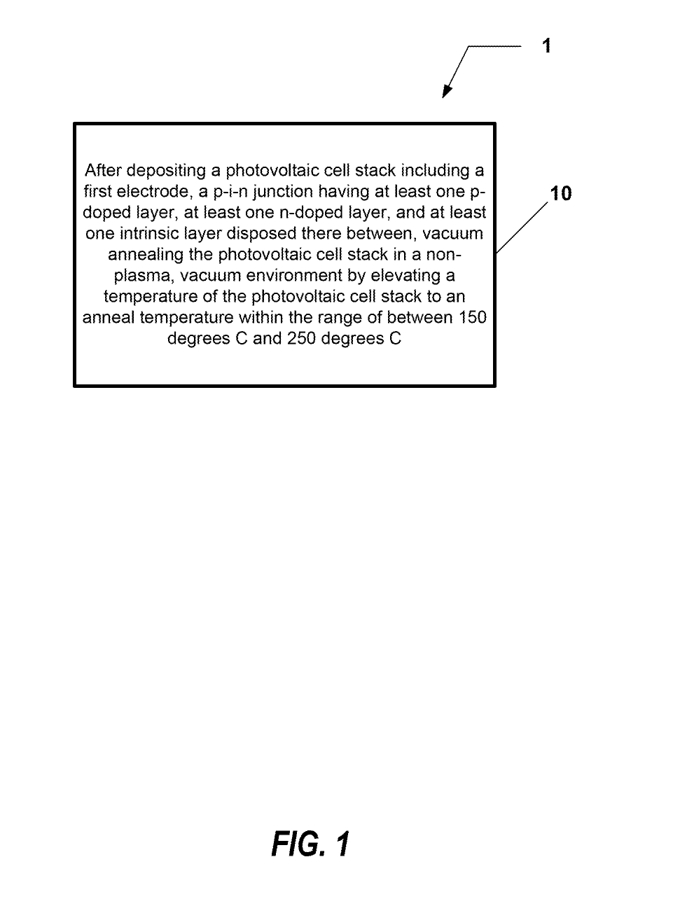

To achieve, among other things, increases in the open circuit voltage (V_{oc}), as well as of the fill factor (FF), a method for annealing a thin film solar cell device is described according to various embodiments. The method is depicted in FIG. 1 as a flow chart 1 that includes, in 10, vacuum annealing an as-deposited photovoltaic cell stack composed of a first electrode, and a p-i-n junction having at least one p-doped layer, at least one n-doped layer, and at least one intrinsic layer disposed there between. The vacuum annealing is performed in a non-plasma, vacuum environment by elevating a temperature of the photovoltaic cell stack to an anneal temperature.

A process condition can be established for performing the vacuum annealing, wherein the process condition includes the anneal temperature, an anneal pressure, and an anneal time duration. The process condition may further include a pre-heating condition that includes setting a pre-heating temperature, a pre-heating temperature ramp rate, a degree of vacuum or pre-heating pressure, a pre-heating gas flow, such as a hydrogen flow rate, etc. The anneal temperature can lie within the range of between 150 degrees C. and 250 degrees C. Alternatively, the anneal temperature can lie within the range of between 200 degrees C. and 250 degrees C. Alternatively yet, the anneal temperature can lie within the range of between 220 degrees C. and 240 degrees C.

The anneal pressure can be less than or equal to 1×10⁻⁶ mbar. Alternatively, the anneal pressure can be less than or equal to 5×10⁻⁶ mbar. The anneal time duration can range up to 120 minutes. Alternatively, the anneal time duration can range up to 60 minutes. Alternatively yet, the anneal time duration can range from 30 to 50 minutes.

The inventors have studied the effect of annealing in vacuum on finished, non-encapsulated PV cells. And, for comparison, the inventors have obtained data for post-deposition hydrogen plasma treatment. In particular, the influence of the hydrogen plasma and the annealing on ZnO front and back electrodes is decoupled from the influence on micro-crystalline or nano-crystalline silicon layers, such as hydrogenated micro-crystalline silicon (μc-Si:H). A micro-crystalline, or nano-crystalline, silicon layer includes a significant fraction of crystalline silicon, referred to at times as micro-crystallites or nano-crystallites, in an amorphous matrix. The inventors have observed that both the μc-Si:H absorber layer and the ZnO back electrodes are affected by such post-deposition treatments, and that the annealing taking place during the treatment has a preponderant role in the improved performance of the solar cells. Most importantly, the inventors surmise that the annealing of complete cells may results in the curing of defects induced by the deposition of the LPCVD ZnO back electrode.

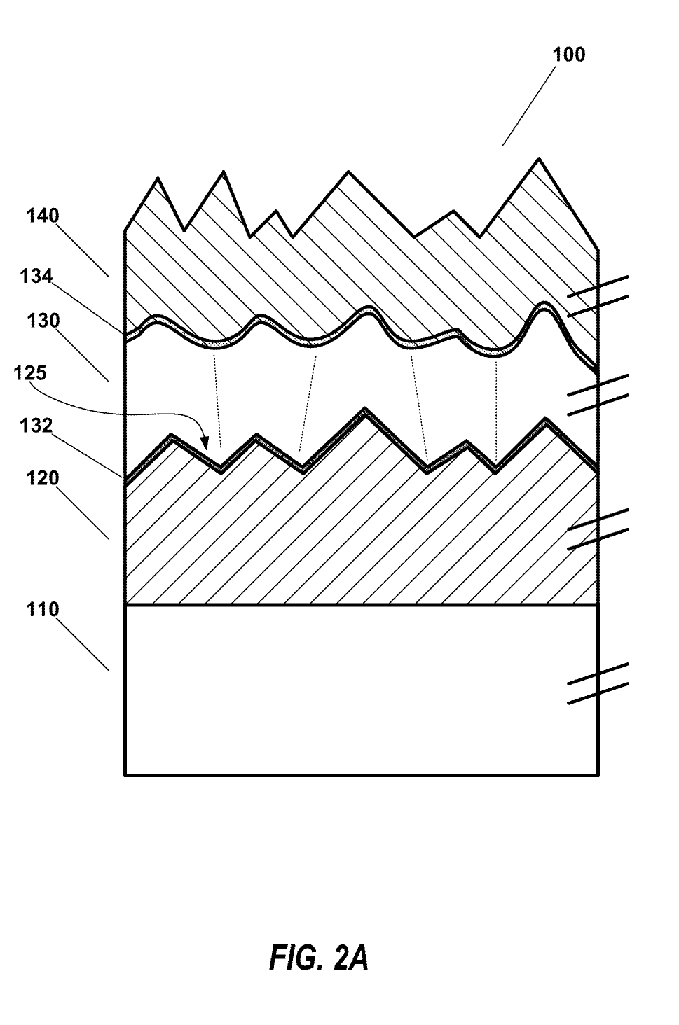

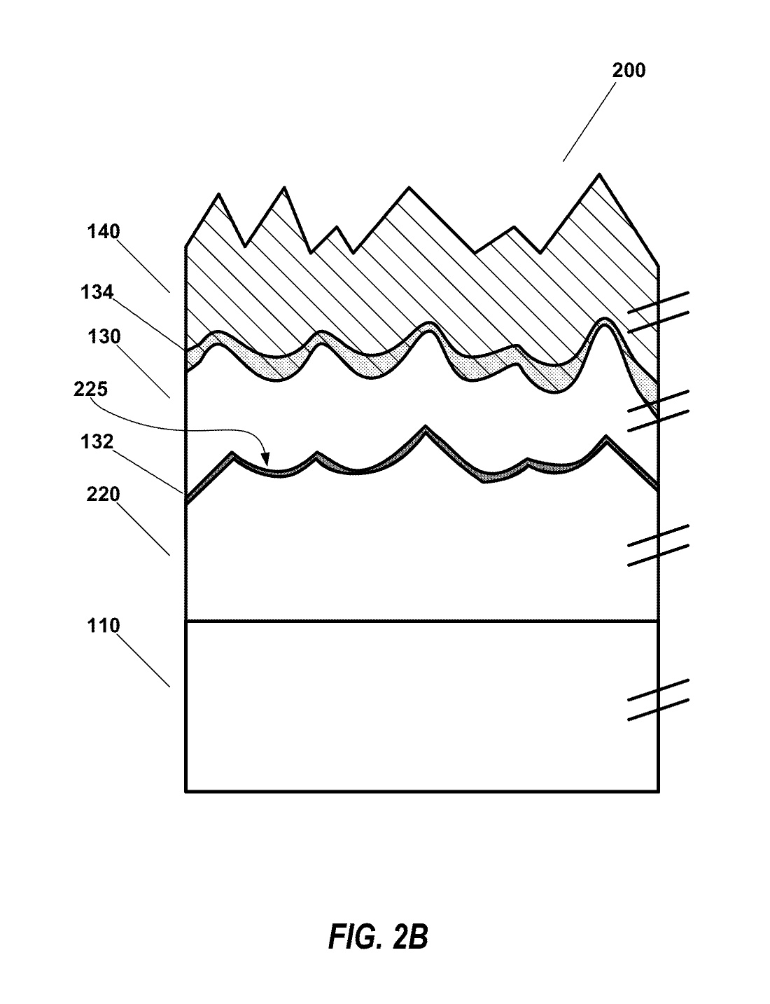

FIGS. 2A and 2B provide a schematic view of p-i-n structure μc-Si:H solar cells used to demonstrate the impact of superstrate roughness (a) and back electrode doping level (b) upon post-deposition treatment (hydrogen plasma or annealing in vacuum). Porous zones, typically appearing when μc-Si:H material is grown on rough superstrate morphology, are represented as dashed lines in the μc-Si:H material (see FIG. 2A).

For assessing the post-treatment technique, PV cell stacks 100, 200 (see FIGS. 2A and 2B) using glass 110 (0.5-mm-thick) coated with a front electrode 120, 220, such as a transparent conductive oxide (TCO) (e.g., highly doped 2-μm thick LPCVD ZnO), were used as a superstrate. By choosing appropriate LPCVD conditions, self-textured ZnO films can be obtained, with as-grown pyramidal-shaped surface features, which provide excellent light trapping for TF Si solar cells. When μc-Si:H solar cells are deposited on rough superstrates, such as rough surface 125 of front electrode 120 in FIG. 2A, porous defective zones (commonly referred to as “cracks”) may appear in the μc-Si:H film depending on the PECVD process conditions for the μc-Si:H film, which then can lead to local post-deposition oxidation and poor cell performance. Alternatively, when μc-Si:H solar cells are deposited on smoother superstrates, such as the smooth surface 225 of front electrode 220 in FIG. 2B, the ZnO surface may be more favorable to the growth of high-quality μc-Si:H material. Prior to μc-Si:H deposition, the front electrode 220 is exposed to an Ar plasma for 4 to 20 minutes to obtain the smooth surface 225 of front electrode 220 having a ZnO surface more favorable to the growth of high-quality μc-Si:H material.

Single-junction solar cells using a p-i-n configuration were deposited by plasma-enhanced chemical vapor deposition (PECVD) at a superstrate temperature of 200 degrees C. The p-i-n configuration included at least one p-doped layer 132, at least one n-doped layer 134, and at least one intrinsic layer 130 disposed there between. The intrinsic layer 130 was deposited with an excitation frequency of 70 MHz, a pressure of 0.7 mbar, and a deposition rate deposition rate of 1.6 Å/s. A thickness of the intrinsic layer of 1.1±0.1 μm was chosen for all experiments, unless stated otherwise explicitly. A back electrode 140 including LPCVD ZnO with a thickness in the range of 2-2.3 μm was used, depending on the experiment.

The solar cells were patterned by lift-off of the ZnO back electrode to define the cell area (0.25 cm² or 1.2 cm²) and dry etched (sulfur hexafluoride/oxygen plasma) to remove silicon between the cells and access the front electrode. A dual-lamp sun simulator from Wacom (WXS-220S-L2 AM1.5G) was used for the measurements of the I-V curves of solar cells under standard test conditions (AM1.5 g, 1000 W/m², 25 degrees C.). V_{oc} and FF were deduced from the resulting I-V curves. J_{sc} was calculated from external quantum efficiency (EQE) measurements or from I-V measurement performed with a dark mask (designated area of 1.05 cm²) in the case of the 1.2-cm²-cells. No anti-reflection coating was applied at the air-glass interface. The sub-gap absorption coefficient at 0.8 eV (α_{0.8}) linked to defects in the bulk phase of the μc-Si:H material was evaluated by Fourier-Transform Photocurrent Spectroscopy (FTPS), scaled with the value of the absorption coefficient of crystalline silicon at 1.35 eV.

Post-deposition treatments with a hydrogen plasma were performed in a plasma enhanced CVD (PECVD) reactor, such as a PECVD reactor for depositing μc-Si. The hydrogen plasma consisted of the following sequence: (i) preheating and outgassing at 200 degrees C. for 20 minutes under vacuum at a pressure of 2×10⁻⁶ mbar, then (ii) exposing to a hydrogen plasma, which was performed at a pressure of 0.5 mbar, a power density of 0.15 W/cm², and a temperature of 200 degrees C. for 20 minutes. Annealing under vacuum was also performed in a PECVD reactor, at a temperature of 230 degree C. for 40 minutes. FIGS. 2A and 2B present a sketch of the PV cells used in order to decouple the impact of annealing in vacuum and hydrogen plasma.

In the first experiment, highly doped 2-μm-thick front electrodes 120, 220, and back electrode 140 were used, in order to minimize the change in their electrical properties induced by the post-deposition treatments (hydrogen plasma and vacuum annealing). The only parameter varied was the Ar plasma treatment duration of the front electrode 120, 220 prior to silicon deposition, resulting in the rough surface 125 of front electrode 120 in FIG. 2A and the smooth surface 225 of front electrode 220 in FIG. 2B. It must be noted that these highly doped electrodes are not optimal for high-efficiency μc-Si:H cells, as they are characterized by high free-carrier absorption. They also provide only limited light trapping in the 800-1100 nm wavelength range due to smaller surface feature size. They are, however, less sensitive to post-deposition treatments, and therefore, helpful for decoupling effects in the μc-Si:H absorber layer from effects in ZnO.

In the second experiment, solar cells were grown on a smooth highly doped superstrate (see FIG. 2B), and the influence of the doping level of the ZnO back electrode 140 (which is the part of the cell directly exposed to the hydrogen plasma when applied) was characterized. Two different back electrodes were tested, with the same thickness (2 μm): (1) a highly doped ZnO and a non-intentionally doped ZnO.

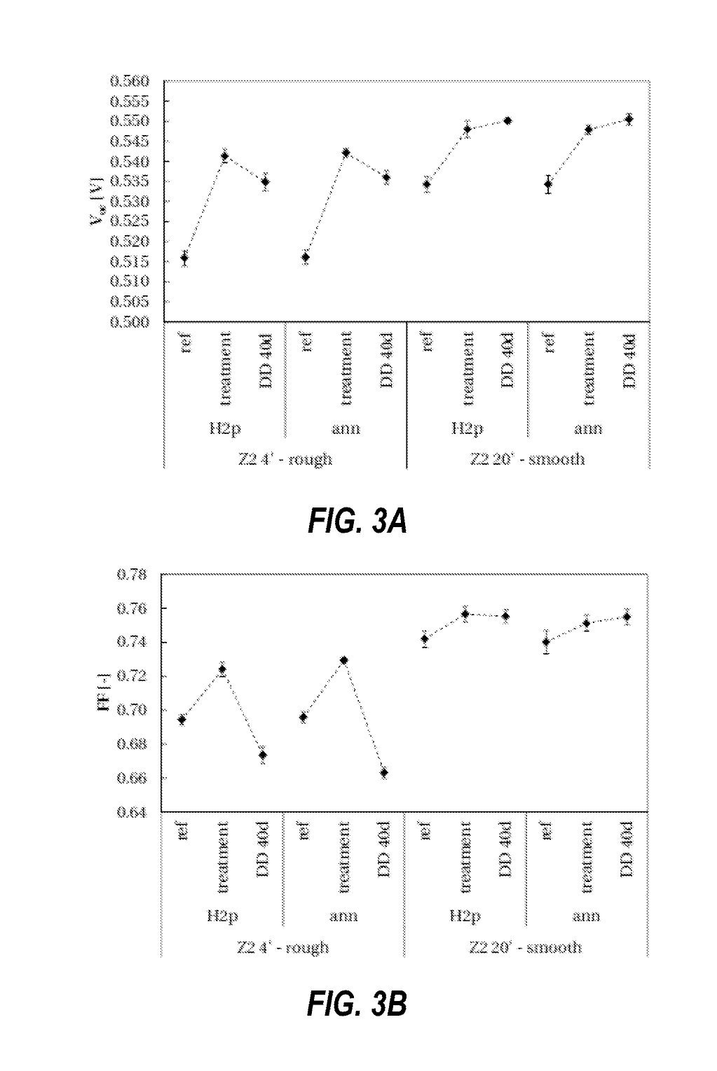

FIGS. 3A and 3B show the effect of a hydrogen plasma (H2p) and vacuum annealing (ann) on the V_{oc} (FIG. 3A) and FF (FIG. 3B) of μc-Si:H solar cells deposited on rough (Z2 4′—rough) and smooth (Z2 20′—smooth) superstrates (averaged over eight 0.25 cm²-cells), and their evolution after 40 days ambient storage in dark (DD 40d). FIGS. 3A and 3B present the changes in V_{oc} and FF when applying different post-deposition treatments on complete cells deposited on rough and smooth superstrates (see FIGS. 2A and 2B). In all cases, an improvement in V_{oc} and FF is observed after the post-deposition treatment, with a strong dependence on the superstrate roughness. In the case of the rough superstrate, the increase is much more pronounced, and very high V_{oc} values above 540 mV are obtained. The inventors surmise that this massive increase is closely related to a curing of the porous, defective zones appearing in the silicon when grown on rougher superstrates.

Note that both vacuum annealing and hydrogen plasma lead to very comparable results in terms of V_{oc} and FF improvements. It has also been determined that the effect does not come from the UV (ultraviolet) illumination of the plasma or the presence of hydrogen by covering the cells with a piece of glass during the plasma. The solar cells deposited on the rough superstrate suffer from dark degradation after storage in dark under ambient atmosphere for 40 days. The solar cells deposited on smooth superstrates remain stable, also after treatment.

The inventors surmise that these results support the hypothesis of moisture in-diffusion through the 2D network of interconnected porous areas present within the μc-Si:H film when deposited on rough superstrates, coming from the edges of the cell which are directly exposed to the atmosphere. Indeed, post-deposition oxidation of this defective material can be related to an increase in the dark saturation current leakage through it, which can happen in a very short time frame as well as on a longer time frame for the post-deposition oxidation of the amorphous tissue surrounding the crystalline grains. A dense material is therefore required to minimize such degradation.

In order to understand the origin of the observed gains, additional experiments were carried out. Additional annealing at 230 degrees C. for 40 minutes were introduced on the solar cells just after the μc-Si:H PECVD step, but before the deposition of the back-electrode, in the following way.

ref: no annealing directly after the μc-Si:H PECVD (reference);

air break+ann: the samples were cooled down to room temperature after the μc-Si:H PECVD, and annealed after a short air break;

direct ann: the samples were annealed directly after the μc-Si:H PECVD, without air break;

double ann: the samples were annealed directly after the μc-Si:H PECVD, and annealed again after a short air break.

Table I presents the effect of various treatments performed before the deposition of the LPCVD ZnO back electrode on the electrical properties of 1-μm-thick μc-Si:H solar cells (ini), and after annealing subsequent to the back-electrode deposition (ann).

Table I shows the changes in V_{oc} and FF for solar cells with different treatments performed before the deposition of the back-electrode (leading to the results labelled “ini”) and after an annealing subsequent to the deposition of the back electrode (leading to the results labelled “ann”). No improvement is observed when various types of annealing are performed before the deposition of the back electrode (“ini” values). The deposition of the back electrode might therefore either cancel a possible gain obtained when annealing the cell before the deposition of the back electrode, or the gain is achieved only when the back electrode is present (improvement of the μc-Si:H/LPCVD ZnO interface).

An improvement similar to the one shown in FIGS. 3A and 3B can be seen only when the solar cells are annealed after the deposition of the LPCVD ZnO back electrode. In that case, an increase of about 20 mV in V_{oc} and 3.2% in FF for the rough (Z2 4′) front electrode is achieved, while the gain remains moderate on the smooth (Z2 20′) front electrode (+5-9 mV in V_{oc} and +1.2-1.8% in FF), regardless of the treatment performed before the deposition of the LPCVD ZnO back electrode. The observed gain is therefore partly linked to the curing of defects induced by the LPCVD ZnO in porous zones of the μc-Si:H absorber layer as no improvement is observed when the treatment is applied before the deposition of the LPCVD ZnO back electrode. The LPCVD method for ZnO film preparation can result in the introduction of foreign elements in those porous zones. Exposure to water vapor during the deposition of the LPCVD ZnO at temperature above 150 degrees C. may lead to oxidation of those zones that get cured after annealing.

TABLE 1

| Front | Treatment before | Voc, ini | Voc, ann | FF, ini | FF, ann |
|---|---|---|---|---|---|
| electrode | LPCVD ZnO | [mV] | [mV] | [%] | [%] |
| Smooth | ref | 544 | 552 | 74.1 | 75.7 |
| (Z2 20′) | air break + ann | 544 | 553 | 73.6 | 75.1 |
| | direct ann | 548 | 553 | 74.5 | 75.7 |
| | double ann | 544 | 552 | 73.6 | 75.4 |
| Rough | ref | 527 | 548 | 69.0 | 72.7 |
| (Z2 4′) | air break + ann | 523 | 545 | 69.3 | 73.0 |
| | direct ann | 523 | 543 | 69.2 | 72.7 |
| | double ann | 517 | 537 | 69.0 | 72.2 |

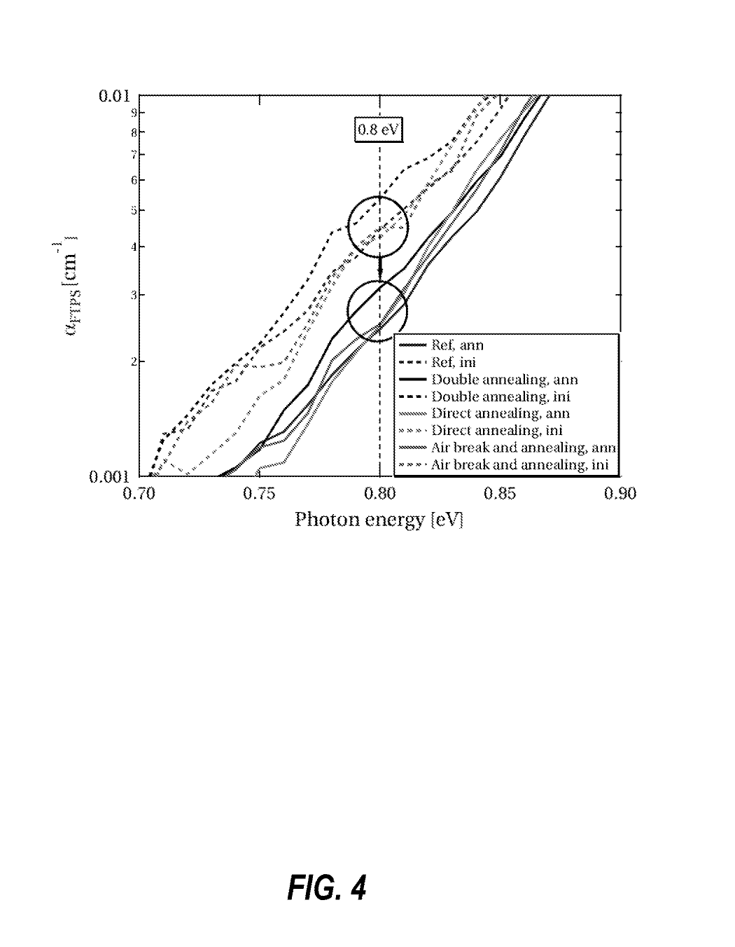

FIG. 4 presents the FTPS measurement of the sub-gap absorption of solar cells deposited on a rough (Z2 4′) LPCVD ZnO, for various types of annealing before the deposition of the back electrode (dashed curves) and re-annealing after the deposition of the back electrode (plain curves). Furthermore, FIG. 4 shows the sub-gap absorption of these same μc-Si:H solar cells (Z2 4′; smooth) as evaluated by FTPS. A strong reduction in α_{0.8} is achieved only if an annealing is performed after the deposition of the LPCVD ZnO back electrode, while no significant change is observed if the cells are annealed before the deposition of the back electrode.

A similar behavior, although much less pronounced, is observed on the smooth superstrate (not shown). This reduction in α_{0.8} is usually associated to a reduction of defects in the bulk μc-Si:H absorber layer. The inventors surmise, however, that one cannot exclude that part of this improvement is related to a reduction of defects within the 2D network of porous and defective material in the μc-Si:H absorber layer. The absolute value of α_{0.8} should be taken with caution as it can depend on the free-carrier density of the front and back electrodes and their morphology.

In Table 2, the evolution of the electrical parameters of solar cells (best cell, with area of 0.25 cm²) exposed to different temperatures of annealing is presented. The cells were deposited on rough (Z2 4′) and the intrinsic μc-Si:H layer has a thickness of 1.35±0.1 μm. “Ref” stands for the parameter measured for the same cell before annealing.

Table 2 shows the performance of solar cells, characterized prior and after annealing in vacuum for different temperatures of annealing. At an annealing temperature of 230 degrees C., a maximal enhancement in V_{oc}×FF was observed without inducing additional collection losses due to potential boron diffusion from the p-doped to the intrinsic layer.

TABLE 2

| Temp, | Voc [mV] | FF [%] | Jsc [mA/cm2] | α_{0.8} [10⁻³ cm⁻¹] |
|---|---|---|---|---|
| [deg. C.] | ref/ann | ref/ann | ref/ann | ref/ann |
| 200 | 515/525 | 67.9/69.3 | 23.1/23.1 | 4.8/3.0 |
| 215 | 513/527 | 68.3/70.8 | 23.1/* | 4.3/3.0 |
| 230 | 514/531 | 68.9/71.5 | 22.9/22.9 | 4.2/2.7 |
| 245 | 510/531 | 69.4/71.5 | 22.9/22.7 | 4.2/2.2 |

An increased reduction of the absorption coefficient at 0.8 eV as measured by FTPS can be seen for increasing temperatures of annealing. The V_{oc} and FF are gradually increased for higher temperatures and tend to saturate at around 230 degrees C., after which point the blue response in the EQE (not shown) of the cell starts to be lowered, due to probable boron-diffusion from the p-doped layer at the p-i interface.

When comparing to hydrogen plasma treatment at 200 degrees C., a temperature of 230 degrees C. was needed to reach the same improvement. The inventors suggest that hydrogen plasma at 200 degrees C. and vacuum annealing at 230 degrees C. lead to similar improvements in V_{oc} and FF due to a plasma-induced temperature increase. Annealing in vacuum is actually sufficient for improving the cell's performance, especially on rough superstrates.

Annealing in vacuum of LPCVD ZnO films already results in a decrease in their sheet resistance. This sheet resistance of the electrodes can be lowered drastically with a hydrogen plasma, especially in the non-intentionally doped (Znid) back electrode case, related to defect passivation at the grain boundaries. Moreover, the improved electrical properties of the ZnO films remain stable upon ambient atmosphere exposure, except for the non-intentionally doped (Znid) back electrode in which case an increase of its sheet resistance is observed when stored in dark ambient atmosphere. In one experiment, the impact on the cell's performance was determined when applying the post-deposition treatments on LPCVD ZnO back electrode with various doping level.

Solar cells were deposited on a smooth superstrate (Z2 20′) used in order to minimize the effect of porous zones in the μc-Si:H absorber layer on the cell performance and to highlight the effect of varying the doping level of the ZnO back electrode.

Table 3 presents the effect of post-deposition treatments on solar cells with different back electrodes. Larger cells (1.2 cm²) were chosen to enhance the impact of the sheet resistance of the back electrode on the FF due to resistive losses. A similar increase in V_{oc} after vacuum annealing and hydrogen plasma is achieved. A very high increase in FF is observed for the cells with the non-intentionally doped (Znid) back electrode. In the case of a highly doped back electrode (Z2), a much smaller enhancement is observed.

Table 3 presents electrical properties of p-i-n μc-Si:H solar cells (best cells, designated aperture area of 1.05 cm²) with non-intentionally doped (Znid) and highly doped (Z2) back electrodes in initial state and after treatment.

TABLE 3

| | | Voc | FF | Rₛₕₑₑₜ |
|---|---|---|---|---|
| Back electrode | Treatment | [mV] | [%] | [Ohms/sq.] |
| Non-intentionally doped | ref/H2p | 526/530 | 48.0/70.9 | 85/24-33 |
| (Znid) | ref/ann | 530/534 | 52.2/69.1 | 85/40-50 |
| Highly doped | ref/H2p | 542/549 | 71.0/72.1 | 10/8 |
| (22) | ref/ann | 545/551 | 72.0/72.6 | 10/8 |

The inventors demonstrated the beneficial effect of post-deposition treatments on finished solar cells and decoupled effects arising from a hydrogen plasma applied on finished, non-encapsulated cells and those coming from annealing taking place simultaneously when performing a hydrogen plasma. More particularly, the inventors observed that annealing the cells under vacuum has a three-fold beneficial effect: (i) improvement of the μc-Si:H bulk material quality, as demonstrated by FTPS leading to an increase up to 10-15 mV without dependence on the superstrate roughness, (ii) a curing of the porous phase in the μc-Si:H absorber layer which can be affected by post-deposition oxidation, as well as (iii) a decreased sheet resistance of the LPCVD ZnO, which effect on cell performance depends on the cell geometry.

Smooth front electrodes or a robust PECVD process are anyway required to avoid the formation of porous zones within the μc-Si:H absorber layer and ensure good stability upon ambient storage. These treatments are fully compatible with an industrial process, offering the possibility to use larger stripes for laser scribing or less doped ZnO back electrodes for equivalent resistive losses in modules, and therefore also reducing the losses induced by dead areas after laser scribing.

The vacuum annealing process may be performed to treat single junction cells, such as the micro-crystalline Si cell described above. Alternatively, the vacuum annealing process may be performed to treat multi-junction cells. For example, the vacuum annealing process may be performed following the formation of the multi-junction cell, or at any point during the formation of each cell in the multi-junction cell. The multi-junction cell can include one or more junctions selected from the group consisting of an amorphous silicon cell, a micro-crystalline silicon cell, a micro-crystalline silicon-germanium cell, a micro-crystalline germanium cell, a chalcopyrite-containing cell, a CdTe cell, CIGS cell, or a CIS cell.

Although only certain embodiments of this invention have been described in detail above, those skilled in the art will readily appreciate that many modifications are possible in the embodiments without materially departing from the novel teachings and advantages of this invention. Accordingly, all such modifications are intended to be included within the scope of this invention.

1. A method for annealing a thin film solar cell device, comprising:
after depositing a photovoltaic cell stack including a first electrode, a p-i-n junction having at least one p-doped layer, at least one n-doped layer, and at least one intrinsic layer disposed there between, and a second electrode, vacuum annealing said photovoltaic cell stack in a non-plasma, vacuum environment by elevating a temperature of said photovoltaic cell stack to an anneal temperature within the range of between 150 degrees C. and 250 degrees C.

2. The method of claim 1, wherein said anneal temperature is elevated to within the range of between 200 degrees C. and 250 degrees C.

3. The method of claim 1, wherein said anneal temperature is elevated to within the range of between 220 degrees C. and 240 degrees C.

4. The method of claim 1, wherein said vacuum environment is characterized by an anneal pressure less than or equal to 1×10⁻⁵ mbar.

5. The method of claim 1, wherein said vacuum environment is characterized by an anneal pressure less than or equal to 5×10⁻⁶ mbar.

6. The method of claim 1, wherein said p-i-n junction comprises at least one microcrystalline silicon (μc-Si) layer.

7. The method of claim 1, wherein said at least one intrinsic layer comprises a hydrogen-doped microcrystalline silicon (μc-Si:H) layer.

8. The method of claim 1, wherein said first electrode comprises a transparent conductive oxide (TCO).

9. The method of claim 1, wherein said first electrode comprises a zinc oxide (ZnO) layer deposited using chemical vapor deposition (CVD).

10. The method of claim 1, wherein said vacuum annealing excludes an intentional introduction of a background gas.

11. The method of claim 1, wherein said vacuum annealing includes an intentional introduction of a background gas.

12. The method of claim 11, wherein said background gas includes hydrogen, nitrogen, or a noble gas, or a mixture thereof.

13. The method of claim 1, further comprising:
performing a plasma treatment of said p-i-n junction before or after said vacuum annealing.

14. The method of claim 13, wherein said plasma treatment includes forming a hydrogen plasma.

15. The method of claim 1, further comprising:
establishing a process condition for performing said vacuum annealing, said process condition including said anneal temperature, an anneal pressure, and an anneal time duration; and
achieving an increase in an open circuit voltage for said p-i-n junction that exceeds 2% of the open circuit voltage for said p-i-n junction as-deposited.

16. The method of claim 1, further comprising:
establishing a process condition for performing said vacuum annealing, said process condition including said anneal temperature, an anneal pressure, and an anneal time duration; and
achieving an increase in an open circuit voltage for said p-i-n junction that exceeds 5% of the open circuit voltage for said p-i-n junction as-deposited.

17. The method of claim 1, wherein said second electrode comprises a zinc oxide (ZnO) layer deposited using chemical vapor deposition (CVD).

18. The method of claim 1, wherein said p-i-n junction is formed between said first electrode and said second electrode.

19. The method of claim 1, further comprising:
forming another solar cell junction electrically in series with said p-i-n junction before or after said vacuum annealing.

20. The method of claim 19, wherein said another solar cell junction includes one or more junctions selected from the group consisting of an amorphous silicon cell, a micro-crystalline silicon cell, a micro-crystalline silicon-germanium cell, a micro-crystalline germanium cell, a chalcopyrite-containing cell, a CdTe cell, CIGS cell, or a CIS cell.
